(19) United States
(12) Patent Application Publication
(10) Pub. No.: US 2008/0087940 A1
(43) Pub. Date: Apr. 17, 2008

(54) Nonvolatile memory device and method of fabricating the same

(75) Inventors: Soo-doo Chae, Yongin-si (KR); Chung-woo Kim, Suwon-si (KR); Chan-jin Park, Yongin-si (KR); Jeong-hee Han, Hwaseong-si (KR); Byung-gook Park, Seoul (KR); Il-han Park, Seoul (KR)

Correspondence Address: LEE & MORSE, P.C., 3141 FAIRVIEW PARK DRIVE, SUITE 500, FALLS CHURCH, VA, 22042, US

(73) Assignee: Samsung Electronics Co., Ltd.

(21) Appl. No.: 11/589,994

(22) Filed: Oct. 31, 2006

(30) Foreign Application Priority Data
Oct. 17, 2006 (KR) 10-2006-0100947

(51) Int. Cl. H01L 29/792; H01L 21/8238

(52) U.S. Cl. 257/324; 438/216; 257/E29.309

(57) ABSTRACT

A nonvolatile memory device, includes a semiconductor substrate having a bottom part, a second vertical part positioned vertically on the bottom part, and a first vertical part having a width smaller than a width of the second vertical part and positioned on the second vertical part to have a boundary step therebetween; a charge trap layer disposed on a lateral surface of the first vertical part and on an upper surface of the boundary step; and a control gate electrode disposed on an upper surface of the bottom part and on lateral surfaces of the second vertical part and the charge trap layer.

### BACKGROUND OF THE INVENTION

1. Field of the Invention

The present invention relates to nonvolatile memory devices. In particular, the present invention relates to a nonvolatile memory device and a method of fabricating the same having increased electron injection efficiency and improved high integration capabilities.

2. Description of the Prior Art

In general, memory devices refer to semiconductor devices that can retain data, e.g., microcontrollers, credit cards, and so forth. Memory devices may be classified into volatile and non-volatile memory devices. Volatile memory devices, e.g., dynamic random access memory (DRAM) and static random access memory (SRAM), may have fast data input/output characteristics but may lose data upon cutting off power supply. Nonvolatile memory devices, e.g., read only memory (ROM), may have relatively slow data input/output characteristics but may retain the input data permanently.

The conventional nonvolatile memory device, e.g., electrically erasable programmable read only memory (EEPROM) device or a flash memory device, may include a semiconductor substrate with a plurality of unit cells having a charge trap layer and a control gate electrode arranged such that data may be electrically programmed and erased by, for example, employing current through a channel between the semiconductor substrate and the charge trap layer, i.e., a channel hot electron injection. In recent years, the size of the conventional unit cells has been decreased to facilitate high-integration chips.

However, the decreased size of the conventional unit cells in nonvolatile memory devices may reduce the length of the channel between the semiconductor substrate and the charge trap layer, thereby triggering a short channel effect and reduced electron injection efficiency. Additionally, the conventional unit cells in nonvolatile memory devices may be produced by photo-etching, a process that may trigger misalignment thereof when the unit cells have decreased size. In particular, the decreased size may generate misalignment of the charge trap layer and/or the control gate electrode, thereby deteriorating memory capabilities of the device and reducing the potential for high-degree integration of nonvolatile memory devices.

### SUMMARY OF THE INVENTION

The present invention is therefore directed to a nonvolatile memory device and a method of fabricating the same, which substantially overcome one or more of the problems due to the limitations and disadvantages of the related art.

It is therefore a feature of an embodiment of the present invention to provide a memory device having increased electron injection efficiency.

It is another feature of an embodiment of the present invention to provide a method of fabricating a memory device having increased electron injection efficiency and minimized misalignment.

At least one of the above and other features of the present invention may be realized by providing a nonvolatile memory device, including a semiconductor substrate having a bottom part, a second vertical part positioned vertically on the bottom part, and a first vertical part having a width smaller than a width of the second vertical part and positioned on the second vertical part to have a boundary step therebetween; a charge trap layer disposed on a lateral surface of the first vertical part and on an upper surface of the boundary step; and a control gate electrode disposed on an upper surface of the bottom part and on lateral surfaces of the second vertical part and the charge trap layer. The semiconductor substrate may have a step-like structure.

The nonvolatile memory device may further include a first insulation layer interposed between the semiconductor substrate and the charge trap layer and a second insulation layer interposed between the semiconductor substrate and the control gate electrode. The second insulation layer may be disposed on the entire upper surface of the bottom part. Alternatively, the second insulation layer may be vertically aligned with an outer surface of the control gate electrode.

The nonvolatile memory device may also include a first source/drain region on an upper surface of the first vertical part and a second source/drain region on an upper surface of the bottom part. The nonvolatile memory device may also include a hard mask.

The charge trap layer may be vertically aligned with the second vertical part. Additionally, the charge trap layer may surround the first vertical part. Further, the charge trap layer may be divided into at least two portions. The charge trap layer may include any one of poly-silicon doped with n-type or p-type impurities, a metal, silicon nitride, silicon oxynitride, or a high-dielectric-constant material.

In another aspect of the present invention, there is provided a method of fabricating a nonvolatile memory device, including etching a semiconductor substrate to form a vertical part projected from a horizontal part, disposing a charge trap coating on an upper surface of the horizontal part and a lateral surface of the vertical part to form a charge trap layer, etching the horizontal part to form a bottom part, a first vertical part, and a second vertical part between the first vertical part and the bottom part, such that the second vertical part is vertically aligned with the charge trap layer, and forming a control gate electrode on an upper surface of the bottom part, such that the control gate electrode is in communication with a lateral surface of the second vertical part and an outer side of the charge trap layer.

Etching the semiconductor substrate to form a first vertical part may include forming a hard mask on the semiconductor substrate as an etching mask.

Disposing the charge trap layer may include performing an anisotropic etching. Additionally, disposing the charge trap layer may include applying any one of metal, poly-silicon doped with n-type or p-type impurities, silicon nitride, silicon oxynitride, or a high-dielectric-constant material.

Forming the control gate electrode may include performing anisotropic etching.

The method of fabricating the nonvolatile memory device may further include removing the hard mask after forming the control gate electrode.

Removing the hard mask may include chemical mechanical polishing (CMP) or etch-back processing.

The method of fabricating the nonvolatile memory device may also include forming a first insulation layer after forming the first vertical part and forming a second insulation layer after forming the second vertical part.

Additionally, the method of fabricating the nonvolatile memory device may include forming source/drain regions on an upper surface of the first vertical part and on an upper surface of the bottom part.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a top view of a memory device according to an embodiment of the present invention;

FIG. 2 illustrates a cross-sectional view taken along line II-II′ of the memory device illustrated in FIG. 1;

FIG. 3 illustrates a cross-sectional view of a memory device according to another embodiment of the present invention;

FIG. 4 illustrates a cross-sectional view of a memory device according to another embodiment of the present invention;

FIG. 5 illustrates a cross-sectional view of a memory device according to another embodiment of the present invention; and

FIGS. 6 to 14 illustrate cross-sectional views of method steps illustrating fabrication of a memory device according to an embodiment of the present invention.

### DETAILED DESCRIPTION OF THE INVENTION

Korean Patent Application No. 10-2006-0100947 filed on Oct. 17, 2006, in the Korean Intellectual Property Office, and entitled: “Nonvolatile Memory Device and Method of Fabricating the Same,” is incorporated by reference herein in its entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will further be understood that when an element is referred to as being “on” another element, layer or substrate, it can be directly on the other element, layer or substrate, or intervening elements or layers may also be present. Further, it will be understood that when an element or layer is referred to as being “under” another element or layer, it can be directly under, or one or more intervening elements or layers may also be present. In addition, it will also be understood that when an element or layer is referred to as being “between” two elements or layers, it can be the only element or layers between respective two elements or layers, or one or more intervening elements or layers may also be present. Like reference numerals refer to like elements or layers throughout.

As used herein, the term “and/or” may include any and all combinations of one or more of the associated listed items.

As further used herein, the singular forms “a,” “an” and “the” are intended to include the plural forms as well, unless the context clearly indicates otherwise.

Unless otherwise defined, all terminology used herein is given its ordinary meaning in the art, and therefore, should be interpreted within the context of the specification and the relevant art as understood by one of ordinary skill

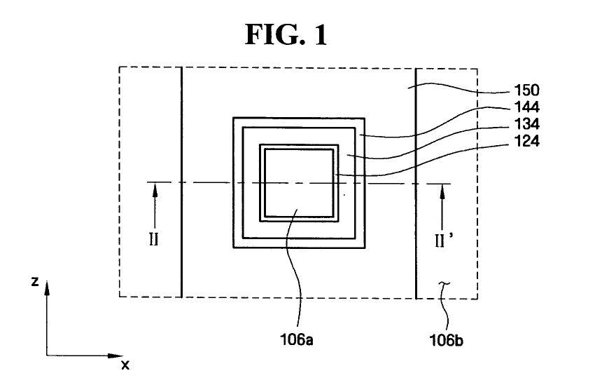

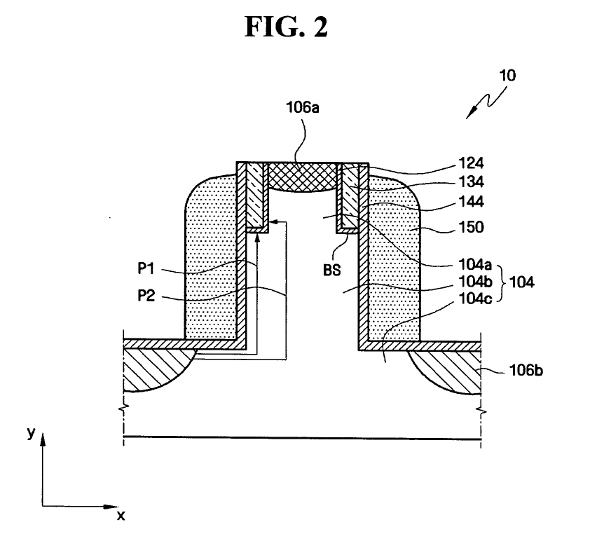

An exemplary embodiment of a nonvolatile memory device according to an embodiment of the present invention will now be more fully described with respect to FIGS. 1-2. It should be noted, however, that the present embodiment refers to a NOR type flash memory device for illustrative purposes only. Accordingly, other types of flash memory devices, e.g., NAND type flash memory device, an EEPROM, and so forth, are not excluded from the scope of the present invention.

As illustrated in FIGS. 1-2, a nonvolatile memory device 10 according to an embodiment of the present invention may include a semiconductor substrate 104, a first source/drain region 106a, a second source/drain region 106b, a charge trap layer 134, and a control gate electrode 150.

The semiconductor substrate 104 of the nonvolatile memory device 10 may be made of any one of silicon (Si), germanium (Ge), silicon-germanium (SiGe), gallium phosphide (GaP), gallium arsenide (GaAs), silicon carbide (SiC), silicon-germanium-carbide (SiGeC), indium arsenide (InAs), indium phosphide (InP), and like materials. Further, the semiconductor substrate 104 may be formed as a p-type substrate or a n-type substrate, and accordingly, it may include a p-type or a n-type well therein for implanting impurities. The semiconductor substrate 104 may be formed to have a bottom part 104c, a first vertical part 104a, and a second vertical part 104b. In this respect, it should be noted that the first and second vertical parts 104a and 104b of the semiconductor substrate 104 may be formed independently with respect to unit cells of the memory device 10.

The bottom part 104c of the semiconductor substrate 104 may extend in a horizontal direction. The second vertical part 104b may have a width smaller than a width of the bottom part 104c as measured along an x-axis, and the second vertical part 104b may extend upward, i.e., along a y-axis, from the bottom part 104c. The first vertical part 104a may have a width smaller than the width of the second vertical part 104b, and the first vertical part 104a may extend upward from the second vertical part 104b, as illustrated in FIG. 2. In other words, the three parts of the semiconductor substrate 104, i.e., the bottom part 104c, the second vertical part 104b, and the first vertical part 104a, may be positioned sequentially one on top of the other to form a step-like structure, as further illustrated in FIG. 2. For example, the step-like structure of the substrate 104 may be symmetrical with respect to a central vertical axis of the memory device 10, i.e., the second vertical part 104b may be positioned in a center of an upper surface of the bottom part 104c, and the first vertical part 104a may be positioned in a center of an upper surface of the second vertical part 104b. However, other configurations are not excluded from the scope of the present invention.

Accordingly, a boundary step BS may be formed to indicate a boundary between the first and second vertical parts 104a and 104b of the semiconductor substrate 104, such that the first vertical part 104a may be positioned above the boundary step BS and the second vertical part 104b may be positioned below the boundary step BS. The boundary step BS may be parallel to the bottom part 104c. However, other configurations of the boundary step BS, e.g., upwards/downward incline, are not excluded from the scope of the present invention.

In this respect, it should be noted that “vertical” as employed in connection with the first and second parts 140a and 140b of the semiconductor substrate 140 of the present invention refers to a perpendicular orientation of a central vertical axis thereof with respect to a central horizontal axis of the bottom part 140c, i.e., a general direction of the first and second vertical parts 140a and 140b of the semiconductor substrate 140 may be perpendicular to a general direction of the bottom part 140c. However, an angle between a surface of a lateral side of either of the first and second vertical parts 140a and 140b of the semiconductor substrate 140 may form any angle, i.e., not necessarily a 90° angle, with respect to an upper surface of the bottom part 140c. In other words, the first, second and bottom parts 140a, 140b and 140c of the semiconductor substrate 140 may have irregular shapes, such that surfaces thereof may form non-perpendicular configuration with respect to one another, as long as the central axes thereof, i.e., central vertical axes of the first and second vertical parts 140a and 140b and central horizontal axis of the bottom part 140c, may be perpendicular to one another. For example, the first vertical part 140a may have a trapezoidal cross-sectional area.

The first and second source/drain regions 106a and 106b of the nonvolatile memory device 10 according to an embodiment of the present invention may be formed on an upper surface of the first vertical part 104a and on peripheral areas of an upper surface of the bottom part 104c, respectively, as illustrated in FIG. 2. Accordingly, an L-shaped channel may be defined between the first source/drain region 106a and the second source/drain region 106b along the surface of the semiconductor substrate 104.

The L-shaped channel may have a predetermined length that may be established by the width of the bottom part 104c of the semiconductor substrate 104 and by respective heights of the first and second vertical parts 104a and 104b. For example, increase of the height of the first and/or second vertical parts 104a and 104b, may increase the overall length of the L-shaped channel, while maintaining the same design rule, i.e., same width of the bottom part 104c of the semiconductor substrate 104. In other words, increasing the height of the first and second vertical parts 140a and 140b may be advantageous for minimizing the size of the unit cell, while maintaining sufficient channel length, thereby improving overall high-degree integration.

The charge trap layer 134 of the nonvolatile memory device 10 according to an embodiment of the present invention may be disposed on an upper surface of the boundary step BS and on lateral surfaces of the first vertical part 104a, i.e., the charge trap layer 134 may be disposed on the boundary step BS to surround the first vertical part 104a and the first source/drain region 106a formed thereon, as illustrated in FIGS. 1-2, to trap electrons injected from the semiconductor substrate 104. Accordingly, the charge trap layer 134 may be made of any material having superior electron retention characteristics, e.g., poly-silicon doped with n-type or p-type impurities, silicon nitride, silicon oxynitride, and so forth, any material having high dielectric constant, e.g., aluminum oxide (AlOx), hafnium oxide (HfOx), and so forth, any conductive material, e.g., metal, or combinations thereof.

The charge trap layer 134 may have a width, i.e., a distance as measured horizontally along the x-axis, of from about 30 angstroms to about 100 angstroms. In this respect, it should be noted that upon deposition of the charge trap layer 134 on the boundary step BS and on the first vertical part 104a, a surface of an outer side, i.e., a surface along the y-axis, of the charge trap layer 134 and a lateral surface of the second vertical part 104b may be vertically aligned. In this respect it should be noted that the term “inner side” refers to a side closest to a center of a cell of a nonvolatile memory device with respect to a center axis of the cell. Similarly, an “outer side” refers to a side furthest from the center of the cell.

It should further be noted that “vertically aligned” with respect to the present invention refers to a structure or positioning of at least two different layers or elements one on top of the other, such that a surface of an outer or lateral side of one layer or element and a surface of an outer or lateral side of the other layer or element may form one uniform geometric surface along a single plane. Further, “inner/outer sides” refer to layers, e.g., charge trap layer 134, and “lateral sides/surfaces” refer to elements, e.g., substrate 140.

It should be noted, however, that other configurations of the charge trap layer 134 with respect to thickness and first and second vertical parts 140a and 104b are not excluded from the scope of the present invention.

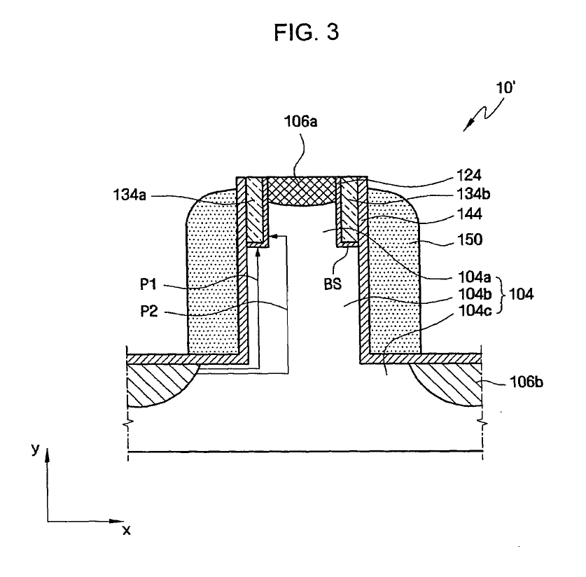

For example, as illustrated in FIG. 3, the charge trap layer 134 may be divided into at least two vertical layers 134a and 134b, as opposed to surrounding the first vertical part 140a. Each of the vertical layers 134a and 134b may be capable of independently trapping electrons, thereby achieving multi-bit programming.

The control gate electrode 150 of the nonvolatile memory device 10 according to an embodiment of the present invention may be formed of a single layer or a composite layer of poly-silicon doped with n-type or p-type impurities or of a conductive material, e.g., metal or metal silicide.

Additionally, the control gate electrode 150 may be disposed on the upper surface of the bottom part 104c of the semiconductor substrate 104 and on the outer side of the charge trap layer 134. In other words, the control gate electrode 150 may be disposed on the bottom part 104c to surround the first and second vertical parts 104a and 104b and the charge trap layer 134. Further, the control gate electrode 150 may be positioned on the bottom part 104c, such that a lower surface of the control gate electrode 150 may overlap with an upper surface of the second source/drain region 106b formed in the bottom part 104c of the semiconductor substrate 104.

Although not illustrated, the control gate electrode 150 may extend to an adjacent unit cell and/or be coupled to a control gate electrode of the adjacent unit cell.

The nonvolatile memory device 10 according to an embodiment of the present invention may further include a first insulation layer 124 and a second insulation layer 144.

The first insulation layer 124 may be formed of any one of silicon oxide, silicon oxide-nitride, and so forth. Additionally, the first insulation layer 124 may be disposed between the charge trap layer 134 and the first and second vertical parts 140a and 140b to provide a path for charge movement between the semiconductor substrate 104 and the charge trap layer 134. For example, electrons moving along the L-shaped channel from the first source/drain region 106a to the second source/drain region 106b may be injected through the insulation layer 124 into the charge trap layer 134.

The second insulation layer 144 may be formed of any one of silicon oxide, silicon oxynitride, a high dielectric constant material, e.g., aluminum oxide (AlOx), hafnium oxide (HfOx), and so forth, or combinations thereof.

Additionally, the second insulation layer 144 may be disposed on the upper surface of the bottom part 104c of the semiconductor substrate 104 and on outer lateral surfaces of the first and second vertical parts 140a and 140b of the semiconductor substrate 140, i.e., between the charge trap layer 134 and the control gate electrode 150, to insulate the control gate electrode and prevent electron movement between the charge trap layer 134 to the control gate electrode 150. For example, application of the second insulation layer 144 to the upper surface of the bottom part 140c may insulate the control gate electrode 150 from the second source/drain region 106b, as shown in FIG. 2.

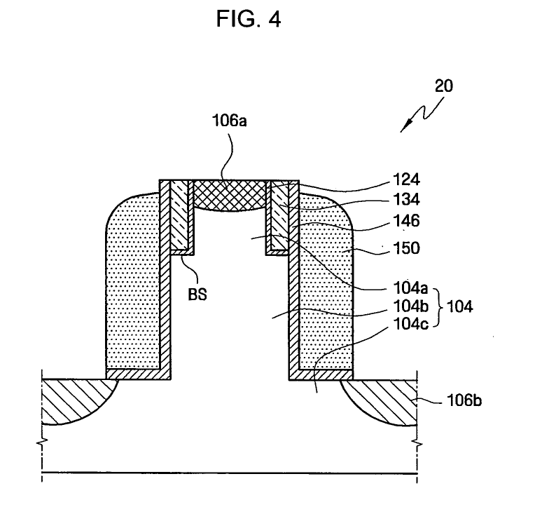

According to another embodiment of the present invention illustrated in FIG. 4, a nonvolatile memory device 20 may be similar to the nonvolatile memory device 10 described with reference to FIGS. 1-2, with the exception that the nonvolatile memory device 20 may include a second insulation layer 146 having a different structure than the second insulation layer 144 of the nonvolatile memory device 10.

In particular, the second insulation layer 146 of the nonvolatile memory device 20 may be formed in a similar manner to the second insulation layer 144 of the nonvolatile memory device 10, except that the insulation layer 146 of the nonvolatile memory device 20 may be disposed on the upper surface of the bottom part 140c of the semiconductor surface 140, such that the second insulation layer 146 may be vertically aligned with the outer surface of the control gate electrode 150, as illustrated in FIG. 4.

Accordingly, the second insulation layer 146 may not affect the operation of the nonvolatile memory device 20 in regions other than a region having an overlap between the control gate electrode 150 and the bottom part 140c of the semiconductor substrate 140. Therefore, the nonvolatile memory device 20 illustrated in FIG. 4 may have the same advantageous structure and operation in terms of electron injection efficiency and high-integration capabilities as described previously with respect to the nonvolatile memory device 10 as illustrated in FIGS. 1-2.

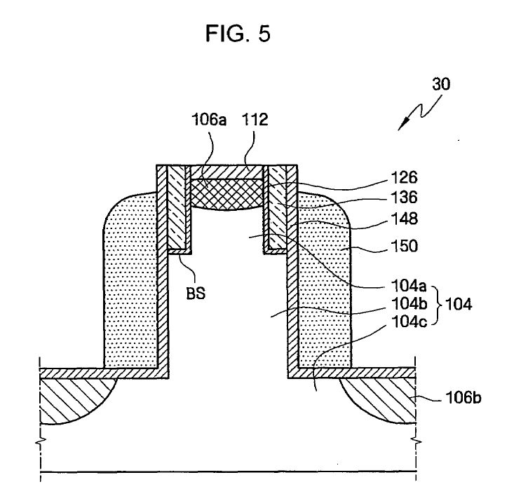

According to another embodiment of the present invention illustrated in FIG. 5, a nonvolatile memory device 30 may be similar to the nonvolatile memory device 10 described with reference to FIGS. 1-2, with the exception that the nonvolatile memory device 30 may include a hard mask 112 on an upper surface of the first vertical part 104a of the semiconductor substrate 104.

In particular, the hard mask 112 may be formed in parallel to the bottom part 104c of the semiconductor substrate 104. Accordingly, the second insulation layer 148, the charge trap layer 136, and the first insulation layer 126 may be extended upward along the y-axis to correspond to a height of the hard mask 112.

The hard mask 112 may not affect the operation of the nonvolatile memory device 30, and therefore, the nonvolatile memory device 30 illustrated in FIG. 5 may have the same advantageous structure and operation in terms of electron injection efficiency and high-integration capabilities as described previously with respect to the nonvolatile memory device 10 as illustrated in FIGS. 1-2.

It should be noted, however, with respect to the embodiment illustrated in FIGS. 1-5, that other elements, e.g., additional inter-layers, insulation layers, contact holes, contact plugs, wires, and so forth, formed on the structures illustrated in FIGS. 1-5 are not excluded from the scope of the present invention.

According to another aspect of the present invention, an exemplary method of operating the nonvolatile memory device 10, i.e., performing a data program operation, is as follows. First, a high voltage may be applied to the control gate electrode 150 to activate the L-shaped channel defined between the second source/drain region 106b and the first source/drain region 106a, i.e., to turn the channel region “on.” In particular, different voltages may be applied to the first and second source/drain regions 106a and 106b to form an electric field therebetween, i.e., along the “turned-on” channel region, and to facilitate electron movement therein. For example, if a higher voltage is applied to the first source/drain region 106a as compared to the second source/drain region 106b, an electric field may be formed from the first source/drain region 106a to the second source/drain region 106b. Accordingly, electrons may move from the second source/drain region 106b to the first source/drain region 106a and, thereby, inject into the charge trap layer 134.

Without intending to be bound by theory, it is believed that electrons moving along the channel may accelerate and, thereby, attain sufficient energy to collide with other electrons and inject into the charge trap layer 134 through the first insulation layer 124 by the channel hot electron injection (CHEI) method. In particular, electrons may move from one source/drain region to another along different paths within the channel. For example, as illustrated in FIG. 2, the electrons may move along a first path P1 that is inside the second vertical part 140b and is in close proximity to a surface thereof. Accordingly, the electrons may be injected into the charge trap layer 134 through the bottom thereof, i.e., the injection into the charge trap layer 134 may occur in the same direction as the movement of the electrons.

Alternatively, as further illustrated in FIG. 2, the electrons may move along a second path P2 that is inside the second vertical part 140b but spaced apart from the surface thereof. Accordingly, the electrons may be injected into the charge trap layer 134 through an inner side thereof, i.e., the injection into the charge trap layer 134 may occur in a direction perpendicular to a direction of movement of the electrons, as illustrated in FIG. 2, thereby requiring more energy as compared to the injection of the electrons through the first path P1. Additionally, it is believed that as a path of the electrons approaches the first path P1, i.e., moves closer to the lateral surface of the second vertical part 140b, the electron density, i.e., number of electrons, increases.

Accordingly, and without intending to be bound by theory, it is believed that injection efficiency of the electrons through the first path P1 may be greater than the injection efficiency of the electrons through the second path P2 due to increased electron density and reduced energy required for injection.

Next, voltage may be applied to move electrons from the charge trap layer 134 to the control gate electrode 150. For example, according to Fowler-Nordheim (F-N) Tunneling method, voltage may be applied to both the first and second source/drain regions 106a and 106b and a high voltage may be applied to the control gate electrode 150, thereby facilitating movement of electrons retained in the charge trap layer 134 into the control gate electrode 150 via the second insulation layer 144. Alternatively, according to another method, ground or negative voltage may be applied to the control gate electrode 150 and high voltage may be applied to the semiconductor substrate 104 and/or the first and second source/drain regions 106a and 106b, thereby facilitating movement of electrons retained in the charge trap layer 134 into the first and second source/drain regions 106a and 106b via the first insulation layer 124.

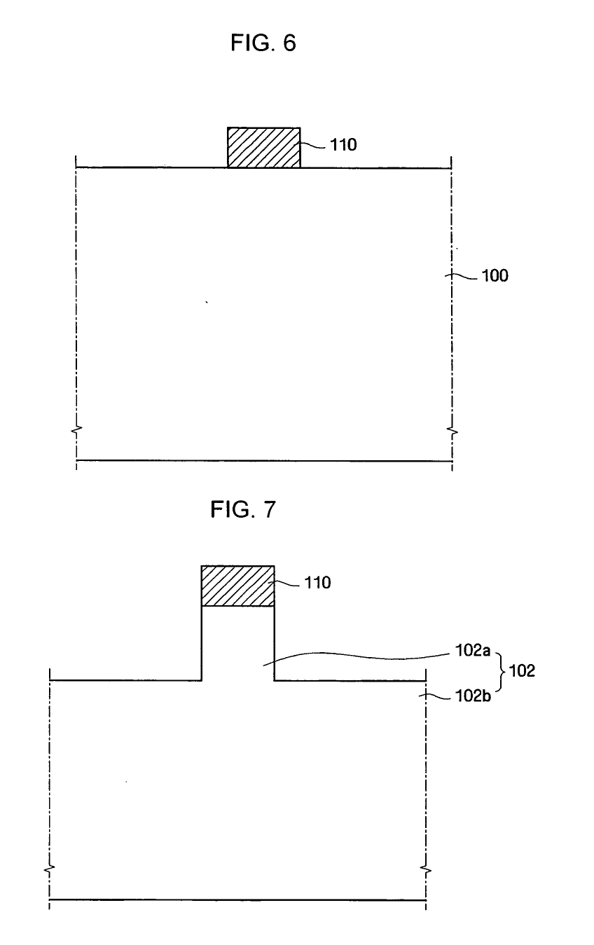

According to another aspect of the present invention, an exemplary method of fabricating the nonvolatile memory devices illustrated in FIGS. 1-5 will be discussed herein with respect to FIGS. 6-14.

As illustrated in FIG. 6, an insulation layer (not shown) may be applied to a substrate 100 and patterned to form a hard mask 110 having a predetermined width. Patterning of an insulation layer is well known in the art and, therefore, will not be discussed herein.

Next, as illustrated in FIG. 7, the semiconductor substrate 100 may be etched, e.g., dry etching, to a predetermined depth using the hard mask 110 as an etching mask to form an etched substrate 102. Accordingly, a vertical part 102a extending vertically from a horizontal part 102b of the etched substrate 102 may be formed.

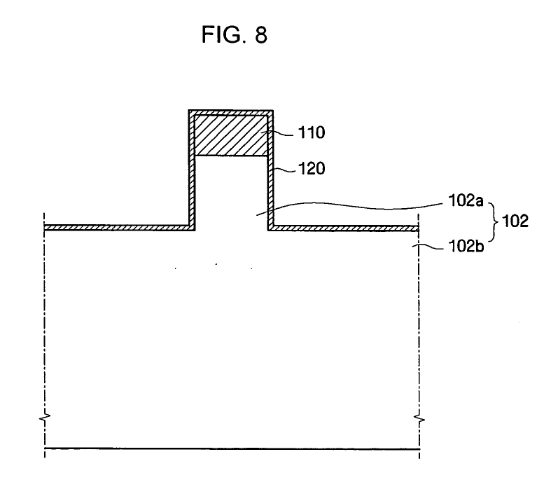

In the next step, as illustrated in FIG. 8, a first insulation coating 120 may be applied to a top of the structure illustrated in FIG. 7, i.e., upper surfaces of the hard mask 110 and horizontal part 102b and lateral surfaces of the vertical part 102a and hard mask 110. The first insulation coating 120, for example, may be formed by chemical vapor deposition (CVD), low pressure chemical vapor deposition (LPCVD), plasma enhanced chemical vapor deposition (PECVD), or thermal oxidation process.

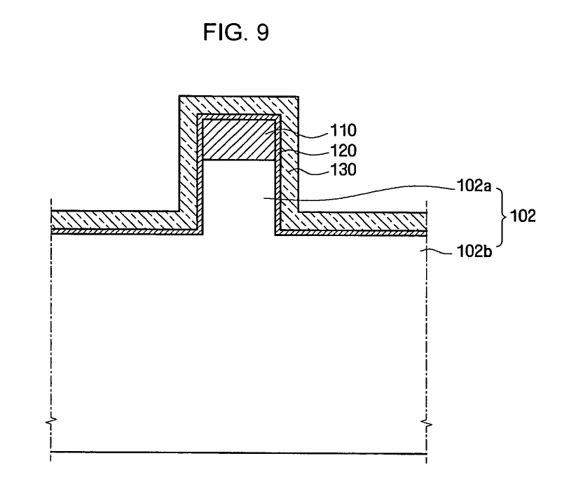

Subsequently, as illustrated in FIG. 9, a charge trap coating 130 may be disposed on the first insulation coating 120. The charge trap coating 130 may be formed of, for example, a conductive material by way of LPCVD, atomic layer deposition (ALD), physical vapor deposition (PVD), metal organic CVD (MOCVD), and so forth. Alternatively, the charge trap coating 130 may be formed of an insulating material by way of CVD, LPCVD, PECVD, thermal oxidation process, or a like process.

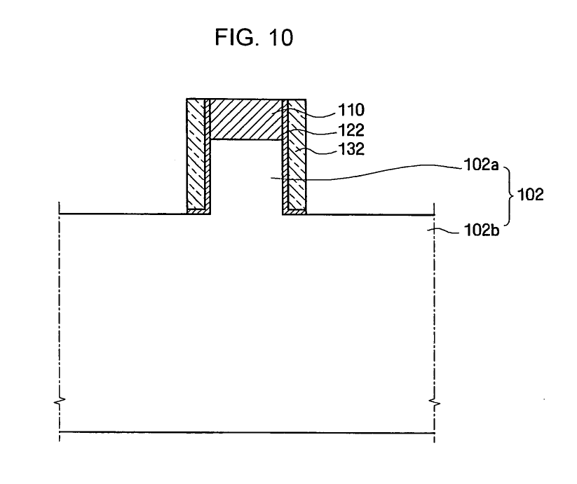

Next, as illustrated in FIG. 10, the charge trap coating 130 and the first insulation coating 120 may be etched by anisotropic etching. The anisotropic etching process is similar to a spacer forming process widely used in a process of fabricating semiconductor devices, and it may be processed in an etch-back process. Consequently, parts of the charge trap coating 130 and the first insulation coating 120 may be removed to expose the upper surface of the horizontal part 102b of the etched substrate 102 and the hard mask 110. The charge trap coating 130 and the first insulation layer 120 may remain on the lateral surfaces of the vertical part 102a and the hard mask 110 to form a first insulation layer 122 and a charge trap layer 132, respectively.

It should be noted with respect to the step illustrated in FIG. 10 that the charge trap layer 132 may be self-aligned and patterned without using photo etching and so forth. Accordingly, misalignment of the charge trap layer 132 may be minimized, thereby improving the reliability of the device.

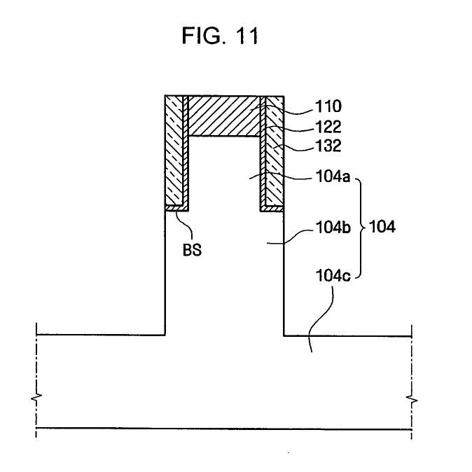

In the next step, illustrated in FIG. 11, the horizontal part 102b of the etched substrate 102 may be etched to a predetermined depth by using the charge trap layer 132, first insulation layer 122, and hard mask 110 as etching masks. Consequently, the upper surface of the bottom part 104c is exposed, and the second vertical part 104b is formed between the bottom part 104c and the first vertical part 104a, i.e., the vertical part 102a becomes the first vertical part 104a. Since the charge trap layer 132 and the bottom part 104c and the first insulation layer 122 may be used as an etching mask, the lateral sides of the second vertical part 104b may be vertically aligned with the charge trap layer 132, such that a combined width of the first vertical part 104a, the first insulation layer 122, and the charge trap layer 132 layer may equal the width of the second vertical part 104b. Further, a projected upper surface of the second vertical part 104b may define a boundary step formed between the first vertical part 104a and the second vertical part 104b.

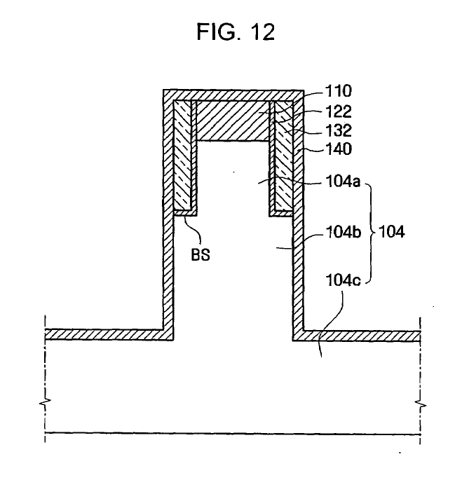

Next, as illustrated in FIG. 12, a second insulation coating 140 may be applied onto an upper surface of the structure in FIG. 1 by any method, such as CVD, LPCVD, PECVD, and so forth.

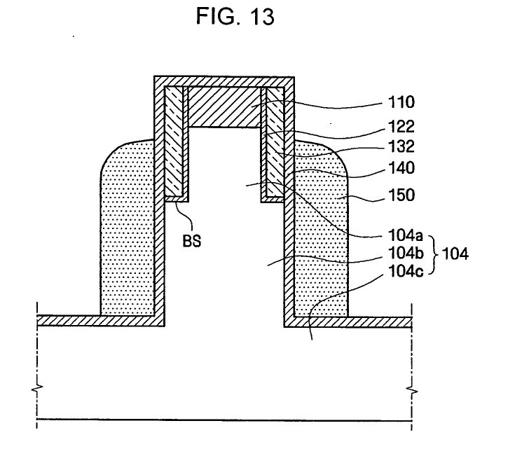

Subsequently, as illustrated in FIG. 13, a conductive layer may be applied onto a front surface of the structure in FIG. 12 by LPCVD, ALD, PVD, MOCVD, and so forth for forming the control gate electrode 150. In particular, the control gate electrode 150, which has a shape similar to a spacer, may be formed by anisotropic etching of the conductive layer. The upper surface of the control gate electrode 150 may be aligned on the upper surface of the first vertical part 104a. Alternatively, the control gate electrode 150 may be formed to have a height lower than the first vertical part 104a of the semiconductor substrate 104.

It should be noted that the control gate electrode 150 may be self-aligned and patterned without using photo etching and so forth, thereby minimizing misalignment of the control gate electrode 150 and increasing the overall reliability of the memory device.

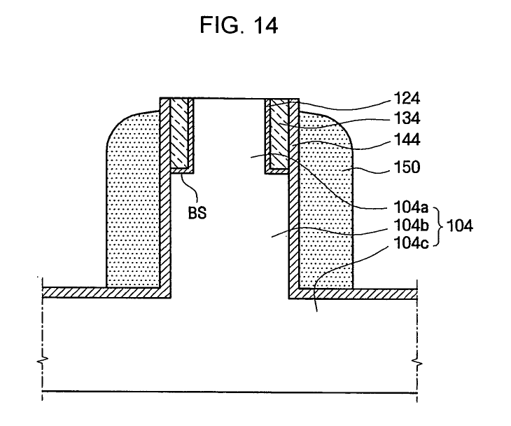

Next, as illustrated in FIG. 14, the structure formed on the first vertical part 104a may be leveled and removed to expose an upper surface of the vertical part 104a, such that the charge trap layer 132, the first insulation layer 122, and the second insulation coating 140 become the charge trap layer 134 and the first and second insulation layers 124 and 144, respectively, illustrated in FIGS. 1-2. The leveling may be performed through a chemical mechanical polishing (CMP) or etch-back process.

In this respect, it should be noted that when the nonvolatile memory device 30 illustrated in FIG. 5 is fabricated, the above-described process may be omitted, or the leveling may be performed only to the extent that the upper surface of the first vertical part 104a is not exposed.

Finally, the exposed first vertical part 104a and bottom part 104c of the semiconductor substrate 104 may be doped with n-type or p-type impurities using the control gate electrode 150 as a doping mask in order to complete the first and second source/drain regions 106a and 106b, as illustrated in FIG. 1.

It should further be noted that when the nonvolatile memory device 20 illustrated in FIG. 4 is fabricated, the insulation coating 140 may be further etched to expose the upper surface of the bottom part 104c of the semiconductor substrate 104.

As described above, the nonvolatile memory device according to the embodiments of the present invention may provide increased electron injection efficiency due to the direction of the electron injection through the bottom surface of the charge trap layer 134. Additionally, the length of the L-shaped channel region may be increased, while maintaining a constant cell width, thereby improving high-integration capabilities. Finally, the charge trap layer 134 and the control gate electrode 150 may be formed by self-alignment, i.e., without using photo etching, thereby minimizing misalignment thereof and improving the reliability of the nonvolatile memory device.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A nonvolatile memory device, comprising:
a semiconductor substrate having a bottom part, a second vertical part positioned vertically on the bottom part, and a first vertical part having a width smaller than a width of the second vertical part and positioned on the second vertical part to have a boundary step therebetween;
a charge trap layer disposed on a lateral surface of the first vertical part and on an upper surface of the boundary step; and
a control gate electrode disposed on an upper surface of the bottom part, lateral surface of the second vertical part, and outer side of the charge trap layer.

2. The nonvolatile memory device as claimed in claim 1, further comprising a first insulation layer interposed between the semiconductor substrate and the charge trap layer and a second insulation layer interposed between the semiconductor substrate and the control gate electrode.

3. The nonvolatile memory device as claimed in claim 2, wherein the second insulation layer is disposed on the entire upper surface of the bottom part of the semiconductor substrate.

4. The nonvolatile memory device as claimed in claim 2, wherein the second insulation layer is vertically aligned with a lateral surface of the control gate electrode.

5. The nonvolatile memory device as claimed in claim 1, further comprising a first source/drain region on an upper surface of the first vertical part and a second source/drain region on an upper surface of the bottom part.

6. The nonvolatile memory device as claimed in claim 1, wherein the semiconductor substrate has a step-like structure.

7. The nonvolatile memory device as claimed in claim 1, wherein the charge trap layer is vertically aligned with the second vertical part.

8. The nonvolatile memory device as claimed in claim 1, wherein the charge trap layer surrounds the first vertical part.

9. The nonvolatile memory device as claimed in claim 1, wherein the charge trap layer is divided into at least two portions.

10. The nonvolatile memory device as claimed in claim 1, wherein the charge trap layer includes any one of poly-silicon doped with n-type or p-type impurities, a metal, silicon nitride, silicon oxynitride, or a high-dielectric-constant material.

11. The nonvolatile memory device as claimed in claim 1, further comprising a hard mask.

12. A method of fabricating a nonvolatile memory device, comprising:
etching a semiconductor substrate to form a vertical part projected from a horizontal part;
disposing a charge trap coating on an upper surface of the horizontal part and a lateral surface of the vertical part to form a charge trap layer;
etching the horizontal part to form a bottom part, a first vertical part, and a second vertical part between the first vertical part and the bottom part, such that the second vertical part is vertically aligned with the charge trap layer; and
forming a control gate electrode on an upper surface of the bottom part, such that the control gate electrode is in communication with a lateral surface of the second vertical part and an outer side of the charge trap layer.

13. The method as claimed in claim 12, wherein etching the semiconductor substrate to form the vertical part comprises forming a hard mask on the semiconductor substrate as an etching mask.

14. The method as claimed in claim 14, further comprising removing the hard mask after forming the control gate electrode.

15. The method as claimed in claim 14, wherein removing the hard mask comprises chemical mechanical polishing (CMP) or etch-back processing.

16. The method as claimed in claim 12, wherein disposing the charge trap coating comprises performing an anisotropic etching.

17. The method as claimed in claim 16, wherein disposing the charge trap coating comprises applying any one of metal, poly-silicon doped with n-type or p-type impurities, silicon nitride, silicon oxynitride, or a high-dielectric-constant material.

18. The method as claimed in claim 12, wherein forming the control gate electrode comprises performing anisotropic etching.

19. The method as claimed in claim 12, further comprising forming a first insulation layer after forming the first vertical part and forming a second insulation layer after forming the second vertical part.

20. The method as claimed in claim 12, further comprising forming source/drain regions on an upper surface of the first vertical part and on an upper surface of the bottom part.
